(19) United States
(12) Patent Application Publication
(10) Pub. No.: US 2026/0227689 A1
(43) Pub. Date: Aug. 6, 2026

(54) PELLICLE FILM ATTACHMENT APPARATUS AND PELLICLE FILM ATTACHMENT METHOD

(71) Applicant: LINTEC Corporation, Tokyo (JP)

(72) Inventor: Takuya HAYASAKA, Tokyo (JP)

(21) Appl. No.: 19/459,400

(22) Filed: Jan. 26, 2026

(30) Foreign Application Priority Data
Jan. 31, 2025 (JP) 2025-015435

(51) Int. Cl. G03F 1/64

(52) U.S. Cl. CPC G03F 1/64

(57) ABSTRACT

A pellicle film attachment apparatus includes: a liquid support unit configured to support a liquid to be adhered to an adherend surface of a frame member; a pellicle film support unit configured to support a pellicle film to be attached to the adherend surface; and a frame conveyance unit configured to convey the frame member and to attach the pellicle film to the frame member, in which the frame conveyance unit is configured to convey the frame member to a liquid adhesion location where the liquid is adhered to the frame member and a pellicle film attachment location where the pellicle film is attached to the frame member.

### CROSS REFERENCE TO RELATED APPLICATIONS

The entire disclosure of Japanese Patent Application No. 2025-015435 filed Jan. 31, 2025 is expressly incorporated by reference herein.

### TECHNICAL FIELD

The present invention relates to a pellicle film attachment apparatus and a pellicle film attachment method.

### BACKGROUND ART

A pellicle film attachment apparatus for attaching a pellicle film to a frame member is known (see, for instance, Literature 1: JP 2017-534078 A).

The apparatus described in Literature 1 includes separate transport units to attach a pellicle 19 (pellicle film) to a pellicle frame 17 (frame member) via a glue (liquid), such as a transport unit that transports a mechanism (liquid support unit) for applying a glue (liquid) to a frame member supported by a support structure 101 and a handling system 113 that transports a pellicle film. The apparatus thus becomes large in size.

### SUMMARY OF THE INVENTION

An object of the invention is to provide a pellicle film attachment apparatus and a pellicle film attachment method that prevent the apparatus from becoming large in size.

An aspect of the invention employs a configuration set forth in the appended claims.

According to the aspect of the invention, a frame conveyance unit conveys a frame member to a liquid adhesion location and a pellicle film attachment location. This makes it possible to reduce the number of the conveyance units and prevent a pellicle film attachment apparatus from becoming large in size.

### BRIEF DESCRIPTION OF DRAWINGS

FIG. 1A illustrates a pellicle film attachment apparatus according to an exemplary embodiment of the invention.

FIG. 1B illustrates the pellicle film attachment apparatus according to the exemplary embodiment of the invention.

### DETAILED DESCRIPTION

Referring to the drawing(s), an exemplary embodiment of the invention will be described below.

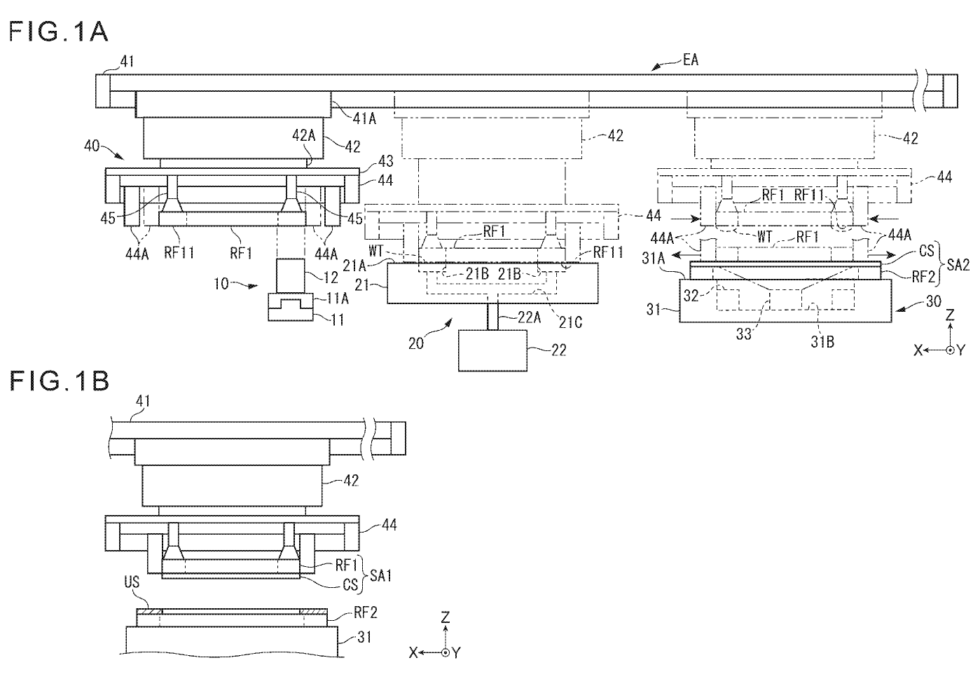

An X-axis, a Y-axis, and a Z-axis in the exemplary embodiment are orthogonal to each other, in which the X-axis and the Y-axis are defined as axes in a predetermined plane and the Z-axis is defined as an axis perpendicular to the predetermined plane. In the exemplary embodiment, in a case where directions are defined as viewed from a near direction in FIG. 1A parallel to the Y-axis as a reference, "up" corresponds to an arrow direction of the Z-axis and "down" is the opposite direction thereto, "left" is an arrow direction of the X-axis and "right" is the opposite direction thereto, and "front" is the near direction in FIG. 1A parallel to the Y-axis and "rear" is the opposite direction thereto.

A pellicle film attachment apparatus EA includes an affinity improvement treatment unit 10, a liquid support unit 20, a pellicle film support unit 30, and a frame conveyance unit 40. The affinity improvement treatment unit 10 performs an affinity improvement treatment step of performing, on an adherend surface RF11 of a first frame member RF1 as a frame member, an affinity improvement treatment to improve an affinity for water WT as a liquid. The liquid support unit 20 performs a liquid support step of supporting the water WT to be adhered to the adherend surface RF11 of the first frame member RF1. The pellicle film support unit 30 performs a pellicle film support step of supporting a pellicle film CS to be attached to the adherend surface RF11. The frame conveyance unit 40 performs a frame conveyance step of conveying the first frame member RF1 and attaching the pellicle film CS to the first frame member RF1.

The affinity for a liquid refers to a property in which the adherend surface RF11 for the liquid to adhere to is easily wet with the liquid and the liquid easily spreads over the adherend surface RF11. It is preferred that the affinity improvement treatment refers to a treatment by which a contact angle of the liquid to the adherend surface RF11 after the affinity improvement treatment is lower than that before the affinity improvement treatment.

In the exemplary embodiment, the frame member RF1 and a frame member RF2 each include an annular metal member having a central opening, and the pellicle film CS is sized to cover the opening of each of the frame members RF1 and RF2. The pellicle film CS of the exemplary embodiment is in a form of a sheet including carbon nanotubes. One of surfaces (lower surface) of the pellicle film CS to be attached to the second frame member RF2 forms an attachment body SA2.

The affinity improvement treatment unit 10 includes a linear motor 11 serving as drive equipment, and a plasma irradiator 12 serving as an irradiation unit supported by a slider 11A of the linear motor 11. The affinity improvement treatment unit 10 is configured to perform the affinity improvement treatment on the first frame member RF1 conveyed by the frame conveyance unit 40.

The liquid support unit 20 includes a table 21 and a liquid supply unit 22, such as a pressure pump or a turbine, that supplies the water WT to the table 21.

The table 21 has a support surface 21A and a flow path 21C. The support surface 21A is provided with a liquid supply port(s) 21B to which the water WT is supplied. The flow path 21C is connected to the liquid supply unit 22 through a pipe 22A and communicates with the liquid supply port 21B.

The pellicle film support unit 30 includes a table 31 that supports the attachment body SA2, a heating unit 32, such as a coil heater or a heating side of a heat pipe, serving as a dryer that dries the pellicle film CS, and a laser cutter 33, serving as a cutter, that cuts the pellicle film CS.

The table 31 has a support surface 31A and a recess 31B. The support surface 31A is a surface on which the attachment body SA2 can be retained by suction with a non-illustrated decompression unit (retainer) such as a decompression pump or a vacuum ejector. The recess 31B is formed in the support surface 31A, and the laser cutter 33 is supported on a bottom surface of the recess 31B.

The heating unit 32 is in an annular shape along a side surface of the recess 31B, and is supported by the side surface.

The single frame conveyance unit 40 is provided. The frame conveyance unit 40 includes: a linear motor 41 serving as drive equipment; a linear motion motor 42 that is supported by a slider 41A of the linear motor 41 and that serves as drive equipment; a bracket 43 supported by an output shaft 42A of the linear motion motor 42; a chuck cylinder 44 that is supported by the bracket 43, serves as a compression unit that compresses the first frame member RF1, and serves as a holder including a plurality of holding members 44A that hold side surfaces of the first frame member RF1 contiguous to the adherend surface R11; and a suction pad(s) 45 that is supported by the bracket 43 and that serves as a retainer on which a surface of the first frame member RF1 opposite to the adherend surface R11 can be retained by suction with a non-illustrated decompression unit (retainer) such as a decompression pump or a vacuum ejector. The frame conveyance unit 40 is configured to convey the first frame member RF1 to a liquid adhesion location where the water WT is adhered to the first frame member RF1 and a pellicle film attachment location where the pellicle film CS is attached to the first frame member RF1.

Operations of the pellicle film attachment apparatus EA described above will be described.

First, a user of the pellicle film attachment apparatus EA (hereinafter, referred to simply as "user") inputs, via a non-illustrated operation unit such as an operation panel or a personal computer, a signal for starting automatic operation to the pellicle film attachment apparatus EA, the components of which are placed at respective initial positions illustrated by solid lines in FIG. 1A. Subsequently, the user or a non-illustrated conveyance unit such as an articulated robot or a belt conveyor puts the attachment body SA2 on the support surface 31A. The pellicle film support unit 30 then drives a non-illustrated decompression unit to start retaining the attachment body SA2 by suction on the support surface 31A. After that, when the user or non-illustrated conveyance unit conveys the first frame member RF1 to between the holding members 44A and causes the first frame member RF1 to abut against the suction pad 45, the frame conveyance unit 40 drives the non-illustrated decompression unit to start retaining the first frame member RF1 by suction on the suction pad 45. Next, the frame conveyance unit 40 drives the chuck cylinder 44 to hold the side surfaces of the first frame member RF1 with the holding members 44A, as illustrated by two-dot chain lines in FIG. 1A.

Subsequently, the affinity improvement treatment unit 10 performs the affinity improvement treatment by irradiating the adherend surface RF11 with plasma, while the affinity improvement treatment unit 10 drives the linear motor 11 to reciprocate the plasma irradiator 12 frontward and rearward and the frame conveyance unit 40 drives the linear motor 41 to reciprocate the first frame member RF1 leftward and rightward. Accordingly, the affinity of the adherend surface RF11 is improved and the surface is cleaned. Then, the frame conveyance unit 40 drives the linear motor 41 to move the first frame member RF1 above the table 21 and the liquid support unit 20 drives the liquid supply unit 22 to supply the water WT to the liquid supply port 21B. Subsequently, the frame conveyance unit 40 drives the linear motion motor 42 to move the first frame member RF1 downward, causing the water WT supplied to the liquid supply port 21B to adhere to the adherend surface RF11 of the first frame member RF1, as illustrated by two-dot chain lines in FIG. 1A. At this time, the adhering water WT is spread evenly on the affinity improvement treatment-treated adherend surface RF11.

Next, the frame conveyance unit 40 drives the linear motor 41 and the linear motion motor 42 to move the first frame member RF1 upward and then rightward, causing the first frame member RF1 to be positioned above the pellicle film CS. The frame conveyance unit 40 then drives the chuck cylinder 44 to bring the holding members 44A close to each other to compress the first frame member RF1, as illustrated by two-dot chain lines in FIG. 1A. The frame conveyance unit 40 then drives the linear motion motor 42 to move the first frame member RF1 downward as illustrated by two-dot chain lines in FIG. 1A, causing the water WT adhering to the adherend surface RF11 to come into contact with the other of the surfaces (upper surface) of the pellicle film CS. The pellicle film CS is attached to the adherend surface RF11 by the capillary force of the water WT. Subsequently, the pellicle film support unit 30 drives the heating unit 32 to dry the pellicle film CS by heating, and then the frame conveyance unit 40 drives the chuck cylinder 44 so that the holding members 44A move outward to release the compression of the first frame member RF1. Tension is thus applied to the pellicle film CS. Next, the pellicle film support unit 30 drives the laser cutter 33 to direct a laser beam along an outer edge of the adherend surface RF11 as illustrated by the two-dot chain lines in FIG. 1A, thus cutting the pellicle film CS into a predetermined shape.

The frame conveyance unit 40 then drives the linear motion motor 42 to move the first frame member RF1 upward as illustrated in FIG. 1B, thus separating the pellicle film CS in the predetermined shape from the second frame member RF2. Accordingly, the pellicle film CS is transferred to the first frame member RF1, providing an attachment body SA1 with the pellicle film CS attached to the first frame member RF1. The user or the non-illustrated conveyance unit then conveys the attachment body SA1 to a next step and conveys the second frame member RF2 attached with an unnecessary sheet US of the pellicle film CS to a collection unit such as a box or a cassette. Thereafter, the same operation as above is repeated.

According to the above exemplary embodiment, the frame conveyance unit 40 conveys the first frame member RF1 to the liquid adhesion location and the pellicle

film attachment location. This makes it possible to reduce the number of the conveyance units and prevent the apparatus from becoming large in size.

The best configuration, method, and the like for carrying out the invention are disclosed in the above description. The invention, however, is not limited thereto. Thus, although the invention is particularly illustrated and described primarily with respect to a specific exemplary embodiment, those skilled in the art may make various modifications to the above exemplary embodiment in terms of shape, material, numerical quantity, and other detailed configurations without departing from the technical idea and the scope of the object of the invention. Further, the descriptions limiting the shapes, materials, and the like disclosed hereinabove are given as examples to facilitate understanding of the invention, and are not intended to limit the invention. Therefore, descriptions in which components are named without some or all of the limitations on shape, material, and the like are within the scope of the invention.

Moreover, the units and steps in the invention are by no means limited as long as the operations, functions, or steps described in connection with the units and steps are achievable, and are in no way limited to the merely exemplary components or steps described in the above exemplary embodiment. For instance, the liquid support unit may be any unit capable of supporting a liquid to be adhered to the adherend surface of the frame member, and is by no means limited insofar as being, in light of common technical knowledge in the art at the time of the filing the present application, within a technical scope of the knowledge (the same applies to any other units and steps).

The affinity improvement treatment unit 10 may perform the affinity improvement treatment on the adherend surface RF11 of the first frame member RF1 before the first frame member RF1 is held by the chuck cylinder 44, may perform the affinity improvement treatment on a plurality of first frame members RF1 at once, and may cause the adherend surface RF11 to face the water WT after performing the affinity improvement treatment in a state where the adherend surface RF11 faces the upper side or lateral side.

For instance, the affinity improvement treatment unit 10 may perform the affinity improvement treatment by irradiating the adherend surface RF11 with an energy beam, such as an electron beam or a microwave, using an irradiation unit, such as an electron beam irradiator or a microwave irradiator; the affinity improvement treatment unit 10 may or may not be provided in the pellicle film attachment apparatus EA of the invention; the affinity improvement treatment unit 10 may perform the affinity improvement treatment by heating or cooling the adherend surface RF11; or the affinity improvement treatment unit 10 may perform the affinity improvement treatment by applying a chemical to the adherend surface RF11. Any approach is usable with the characteristics, qualities, properties, materials, compositions, configurations, and the like of the first frame member RF1 and the adherend surface RF11 taken into consideration, insofar as the affinity improvement treatment can be performed on the adherend surface RF11.

In the liquid support unit 20, the opening of the liquid supply port 21B may be larger or smaller in shape than the adherend surface RF11 of the first frame member RF1, at least one liquid supply port 21B may be provided, a waste liquid disposal unit that discharges the liquid remained in the liquid supply port 21B may be provided, or a sensing unit that senses the supply amount of the liquid by the liquid supply unit 22, such as a flowmeter or a flow rate sensor, may be provided.

The support surface 21A may be coated with a water-repellent material such as an adhesive or a resin, and thus be liquiphobic, a property that makes the support surface 21A resistant to wetting and spreading of liquid.

Regarding the liquid to be adhered to the adherend surface RF11, any liquid is usable with the characteristics, qualities, properties, materials, compositions, configurations, and the like of the first frame member RF1 and the adherend surface RF11 and the characteristics, qualities, properties, materials, compositions, configurations, and the like of pellicle film CS taken into consideration, insofar as the liquid enables the pellicle film CS to be attached to the adherend surface RF11. For instance, the liquid may be a polar solvent such as a low-molecular alcohol (e.g., isopropyl alcohol, methanol, and ethanol), a mixed solvent of the water WT and an organic solvent, or a molten metal such as solder, lead, tin, iron, and copper, in addition to an adhesive, resin, varnish, paint, and the like. In particular, in terms of letting no material other than the pellicle film CS remain on the adherend surface RF11, the liquid preferably consists of a component evaporable or volatilizable by heat or air drying, and the liquid is preferably the water WT, an organic solvent, or a mixed solvent thereof.

The pellicle film support unit 30 may support the pellicle film CS that is not attached to the second frame member RF2, may include a plurality of heating units, may omit the heating unit 32, may include a cutter so that the cutter can cut the pellicle film CS from above the pellicle film CS, may include a plurality of cutters, and may omit a cutter. When no cutter is provided in the pellicle film support unit 30, the frame conveyance unit 40 may separate the pellicle film CS from the second frame member RF2 without cutting the pellicle film CS.

The dryer may include a spraying unit, such as a spraying tube or a nozzle, through which a heated gas such as air, gas, or the like heated by the heating unit 32 is sprayed, and the pellicle film CS may be dried by spraying the heated gas to the pellicle film CS. The dryer may or may not be provided in the pellicle film attachment apparatus EA of the invention.

The frame conveyance unit 40 may retain the first frame member RF1 by suction on the suction pad 45 after the first frame member RF1 is held by the holding members 44A, may retain the first frame member RF1 by suction on the suction pad 45 simultaneously with holding the first frame member RF1 with the holding members 44A, may hold the first frame member RF1 with a plurality of chuck cylinders 44, may not include one of the chuck cylinder 44 and the suction pad 45, may or may not compress the first frame member RF1, may not hold the first frame member RF1 until the first frame member RF1 is compressed, and may attach the adherend surface RF11 of the first frame member RF1 to one of surfaces of the pellicle film CS.

The holder may hold or compress the first frame member RF1 with drive equipment such as an articulated robot or a mechanical chuck.

The frame members RF1 and RF2 may be formed, for instance, from metal such as stainless steel, aluminum, copper, or brass, resin such as silicone, fluorine resin, or acrylic resin, or a ceramic material. Silicon or quartz with a low thermal expansion coefficient is preferred. Silicon that is easy to be machined into a desired shape is more preferably used. The shape may be a non-annular shape (a shape having a discontinuous circumference), a circle, an oval, a polygon, or any other shape.

The material, type, shape, and the like of the pellicle film CS and the frame members RF1, RF2 in the invention are not particularly limited. For instance, the pellicle film CS and the frame members RF1, RF2 may be in a shape of a circle, an oval, or a polygon such as a triangle or a quadrangle or in any other shape.

Regarding the drive equipment of the above exemplary embodiment, motorized equipment such as a rotary motor, a linear motion motor, a linear motor, a single-axis robot, or a so-called articulated robot having biaxial or tri- or more axial joints, an actuator such as an air cylinder, a hydraulic cylinder, a rodless cylinder, or a rotary cylinder, and the like, may be used alone, or provided by a direct or indirect combination. Or, one capable or incapable of performing a torque control, a speed control, or the like on an output section of the motorized equipment, the actuator, or the like may be used.

In the above exemplary embodiment, an object (hereinafter, referred to as "object A") and another object (hereinafter, referred to as "object B") movable with respect to the object A, that is, relatively movable object A and object B may be defined as follows. The object B may be moved with respect to the immovable object A, the object A may be moved with respect to the immovable object B, or both the object A and the object B may be moved. It does not matter which one of the object A and the object B is to be moved insofar as the movement achieves the same result. In a case where there is provided an element, such as a support (retaining) unit or a support (retaining) member, that supports (retains) a member to be supported (a member to be retained), the member to be supported may be supported (retained) by a holder such as a mechanical chuck or a chuck cylinder, Coulomb force, an adhesive (an adhesive sheet or an adhesive tape), a sticky agent (a sticky sheet or a sticky tape), magnetic force, Bernoulli suction, suction adsorption, drive equipment, or the like. In a case where there is provided an element, such as a cutter unit or a cutting member, that cuts a member to be cut or makes a cut or a cut line in the member to be cut, the cutting may be performed with, in place of or in combination with the above exemplary element, a cutter blade, a laser cutter, ion beam, firepower, heat, hydraulic pressure, heating wire, or an element that performs cutting by spraying or the like of a gas, a liquid, or the like. Or, the cutting may be performed by moving the object to be cut by a combination of appropriate drive equipment.

What is claimed is:

1. A pellicle film attachment apparatus, comprising:
a liquid support unit configured to support a liquid to be adhered to an adherend surface of a frame member;
a pellicle film support unit configured to support a pellicle film to be attached to the adherend surface; and
a frame conveyance unit configured to convey the frame member and to attach the pellicle film to the frame member,
wherein the frame conveyance unit is configured to convey the frame member to a liquid adhesion location where the liquid is adhered to the frame member and a pellicle film attachment location where the pellicle film is attached to the frame member.

2. The pellicle film attachment apparatus according to claim 1, further comprising an affinity improvement treatment unit configured to perform, on the adherend surface of the frame member, an affinity improvement treatment to improve an affinity for the liquid,
wherein the affinity improvement treatment unit is configured to perform the affinity improvement treatment on the frame member conveyed by the frame conveyance unit.

3. The pellicle film attachment apparatus according to claim 1, wherein the frame conveyance unit includes a compression unit configured to compress the frame member.

4. A pellicle film attachment method comprising:
supporting a liquid to be adhered to an adherend surface of a frame member;
supporting a pellicle film to be attached to the adherend surface; and
conveying the frame member and attaching the pellicle film to the frame member using a frame conveyance unit,
wherein, in the conveying of the frame member, the frame member is conveyed, using the frame conveyance unit, to a liquid adhesion location where the liquid is adhered to the frame member and a pellicle film attachment location where the pellicle film is attached to the frame member.
